(19) United States
(12) Patent Application Publication
(10) Pub. No.: US 2003/0137807 A1
(43) Pub. Date: Jul. 24, 2003

(54) Heat dissipating device

(75) Inventor: Cheng-Lung Chen, Hsei-Chih City (TW)

Correspondence Address: MERCHANT & GOULD PC, P.O. BOX 2903, MINNEAPOLIS, MN, 55402-0903, US

(73) Assignee: MITAC INTERNATIONAL CORP., Hsinchu Hsien (TW)

(21) Appl. No.: 10/055,277

(22) Filed: Jan. 22, 2002

(51) Int. Cl. H05K 7/20

(52) U.S. Cl. 361/697; 257/722; 165/80.3

(57) ABSTRACT

A heat dissipating device includes a heat-dissipating fin unit having a base plate with a lower surface disposed in heat-conductive contact with a heat-generating source, and a plurality of fin plates formed integrally on and extending upwardly from an upper surface of the base plate. Adjacent ones of the fin plates are spaced apart from each other so as to form an air guide groove therebetween. A fan unit, which is disposed on top of the fin unit, has a fan blade disposed in a fan housing, and an air guide member extending integrally from the fan housing toward the fin unit so as to confine an air guide region between the fan housing and the fin unit such that air flow generated by the fan blade can be guided to flow toward the fin unit via the air guide region.

### BACKGROUND OF THE INVENTION

1. Field of the Invention

The invention relates to a heat dissipating device, more particularly to a heat dissipating device that has an air guide member for guiding air flow.

2. Description of the Related Art

With the increase in the operational speed of computers, electronic components of the computer are likely to generate a large amount of heat during operation thereof, which can lead to failure of the computer or damage to the electronic components.

FIG. 1 illustrates a conventional heat dissipating device that includes a heat-dissipating fin unit 11 and a fan unit 12. The fin unit 11 has a base plate 10 with a lower surface 111 disposed in heat-conductive contact with a heat-generating source 14, and an upper surface 113 opposite to the lower surface 111. The fin unit 11 further has a plurality of parallel fin plates 115 formed integrally on and extending upwardly from the upper surface 113 of the base plate 11. The fan unit 12 is directly mounted on top of the fin unit 11 in a known manner, and has a fan housing 121, and a fan blade 123 disposed in the fan housing 121. Referring to FIG. 2, air flow generated by the fan blade 123 flows directly and downwardly toward the fin unit 11 (as indicated by the solid arrow lines in FIG. 2). Because a large amount of heat accumulates in a region 13 of the fin unit 11 close to the heat-generating source 14, it is desirable that air flow from the fan unit 12 be concentrated toward the region 13 to improve the heat-dissipating efficiency.

### SUMMARY OF THE INVENTION

Therefore, the object of the present invention is to provide a heat dissipating device with a relatively high heat-dissipating efficiency.

According to the present invention, a heat dissipating device comprises:

a heat-dissipating fin unit having a base plate with a lower surface adapted to be disposed in heat-conductive contact with a heat-generating source, and an upper surface opposite to the lower surface, the fin unit further having a plurality of fin plates formed integrally on and extending upwardly from the upper surface of the base plate, adjacent ones of the fin plates being spaced apart from each other so as to form an air guide groove therebetween; and

a fan unit disposed on top of the fin unit and having a fan housing, and a fan blade disposed in the fan housing, the fan unit further having an air guide member extending integrally from the fan housing toward the fin unit so as to confine an air guide region between the fan housing and the fin unit such that air flow generated by the fan blade can be guided to flow toward the fin unit via the air guide region.

### BRIEF DESCRIPTION OF THE DRAWINGS

Other features and advantages of the present invention will become apparent in the following detailed description of the preferred embodiments with reference to the accompanying drawings, of which:

FIG. 1 is a perspective view of a conventional heat dissipating device;

FIG. 2 is a schematic side view illustrating how air flows in the conventional heat dissipating device;

FIG. 3 is an exploded perspective view showing the first preferred embodiment of a heat dissipating device according to the present invention;

FIG. 4 is a schematic side view illustrating how air flows in the first preferred embodiment;

FIG. 5 is a bottom perspective view showing a fan unit of the second preferred embodiment of a heat dissipating device according to the present invention;

FIG. 6 is a bottom perspective view showing a fan unit of the third preferred embodiment of a heat dissipating device according to the present invention; and

FIG. 7 is a schematic top view showing a fin unit of the fourth preferred embodiment of a heat dissipating device according to the present invention.

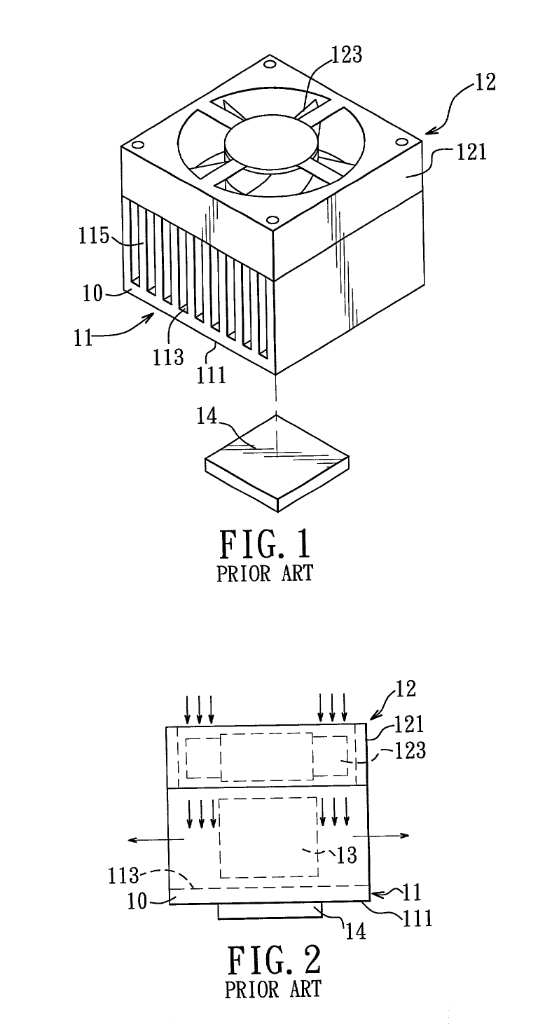

### DETAILED DESCRIPTION OF THE PREFERRED EMBODIMENTS

Before the present invention is described in greater detail, it should be noted that like elements are denoted by the same reference numerals throughout the disclosure.

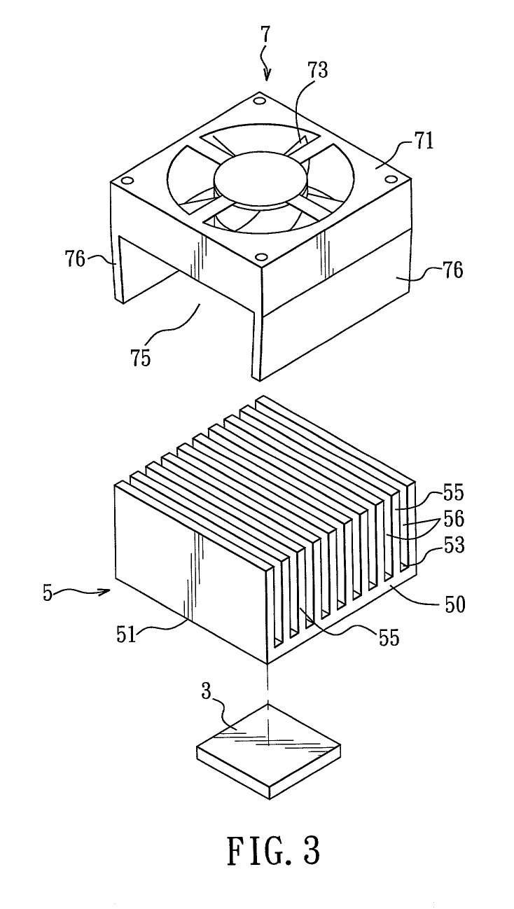

Referring to FIG. 3, the first preferred embodiment of a heat dissipating device according to the present invention is shown to include a heat-dissipating fin unit 5, and a fan unit 7.

The fin unit 5 has a base plate 50 with a lower surface 51 adapted to be disposed in heat-conductive contact with a heat-generating source 3, such as a central processing unit, and an upper surface 53 opposite to the lower surface 51. The fin unit 5 further has a plurality of fin plates 55 formed integrally on and extending upwardly from the upper surface 53 of the base plate 50. Adjacent ones of the fin plates 55 are spaced apart from each other so as to form an air guide groove 56 therebetween. In this embodiment, adjacent ones of the fin plates 55 are parallel to each other in a longitudinal direction.

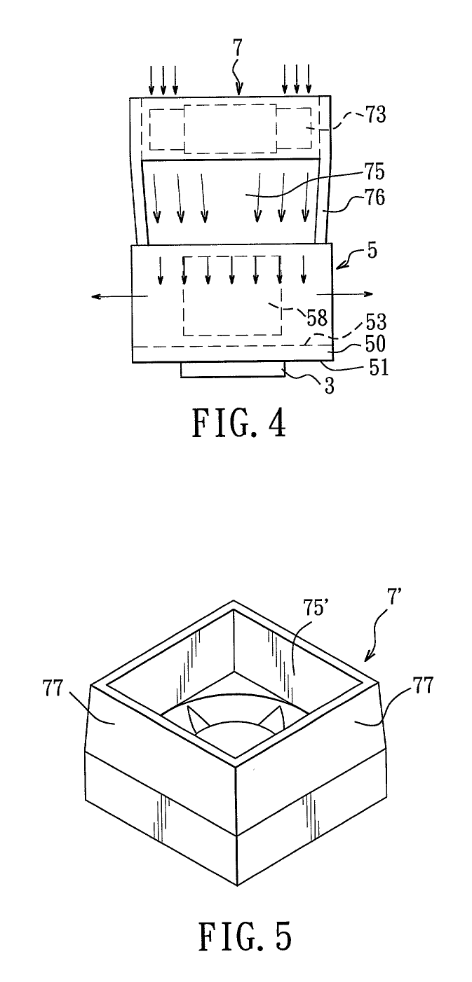

The fan unit 7 is disposed top of the fin unit 5 and has a fan housing 71, and a fan blade 73 disposed in the fan housing 71. The fan unit 7 further has an air guide member extending integrally from the fan housing 71 toward the fin unit 5 so as to confine an air guide region 75 between the fan housing 71 and the fin unit 5 such that air flow generated by the fan blade 73 can be guided to flow toward the fin unit 5 via the air guide region 75. In this embodiment, the air guide member includes a pair of guide plates 76, each of which extends transverse to the longitudinal direction such that air flow generated by the fan blade 73 can be guided to flow toward each air guide groove 56 of the fin unit 5 via the air guide region 75 (as indicated by the solid arrow lines in FIG. 4). Preferably, the air guide region 75 is gradually reduced in size from the fan housing 71 to the fin unit 5.

It is noted that, due to the presence of the guide plates 76 of the air guide member, it is possible for the heat dissipating device of the present invention to guide air flow generated by the fan blade 73 to concentrate toward a region 58 of the fin unit 5, where a large amount of heat accumulates, thereby resulting in a relatively high heat-dissipating efficiency. The object of the invention is thus met.

FIG. 5 illustrates the second preferred embodiment of a heat dissipating device according to the present invention, which is a modification of the first preferred embodiment. Unlike the previous embodiment, the air guide member of the fan unit 7′ includes a funnel 77 that confines the air guide region 75′ with a rectangular cross-section.

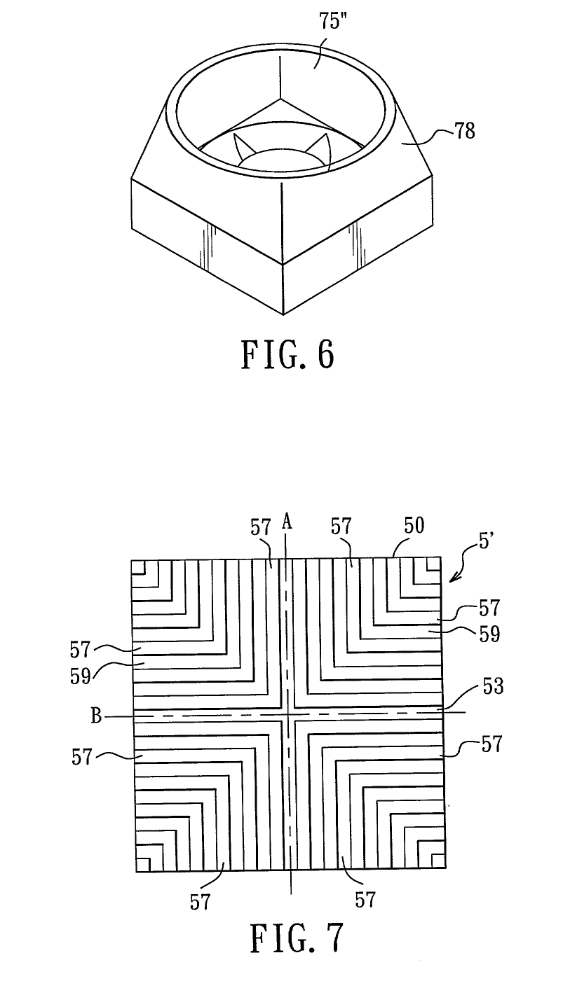

FIG. 6 illustrates the third preferred embodiment of a heat dissipating device according to the present invention, which is a modification of the second preferred embodiment. Unlike the second preferred embodiment, the funnel 78 confines the air guide region 75″ with a circular cross-section.

FIG. 7 illustrates the fourth preferred embodiment of a heat dissipating device according to the present invention, which is a modification of the first preferred embodiment. Unlike the first preferred embodiment, the base plate 50 of the fin unit 5′ is rectangular. The fin plates 57 include four sets of a plurality of L-shaped fin plates 57. Each of the sets of the L-shaped fin plates is provided on a quarter area of the upper surface 53 of the base plate 50. Adjacent ones of the sets of the L-shaped fin plates 57 are symmetrical to each other relative to one of a pair of orthogonal axes (A, B). As such, a larger number of the air guide grooves 59 is configured as compared to the above-mentioned embodiments so as to further improve the heat-dissipating efficiency.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

I claim:

1. A heat dissipating device comprising:
a heat-dissipating fin unit having a base plate with a lower surface adapted to be disposed in heat-conductive contact with a heat-generating source, and an upper surface opposite to said lower surface, said fin unit further having a plurality of fin plates formed integrally on and extending upwardly from said upper surface of said base plate, adjacent ones of said fin plates being spaced apart from each other so as to form an air guide groove therebetween; and
a fan unit disposed on top of said fin unit and having a fan housing, and a fan blade disposed in said fan housing, said fan unit further having an air guide member extending integrally from said fan housing toward said fin unit so as to confine an air guide region between said fan housing and said fin unit such that air flow generated by said fan blade can be guided to flow toward said fin unit via said air guide region.

2. The heat dissipating device as claimed in claim 1, wherein adjacent ones of said fin plates are parallel to each other in a longitudinal direction.

3. The heat dissipating device as claimed in claim 1, wherein said base plate of said fin unit is rectangular, said fin plates including four sets of a plurality of L-shaped fin plates, each of said sets of said L-shaped fin plates being provided on a quarter area of said upper surface of said base plate, adjacent ones of said sets of said L-shaped fin plates being symmetrical to each other relative to one of a pair of orthogonal axes.

4. The heat dissipating device as claimed in claim 1, wherein said air guide member includes a pair of guide plates, each of which extends transverse to said fin plates.

5. The heat dissipating device as claimed in claim 1, wherein said air guide member includes a funnel.

6. The heat dissipating device as claimed in claim 1, wherein said air guide region is gradually reduced in size from said fan housing to said fin unit.
